(19) United States
(12) Patent Application Publication
(10) Pub. No.: US 2015/0056940 A1
(43) Pub. Date: Feb. 26, 2015

(54) HARMONIC TRAP FOR COMMON GATE AMPLIFIER

(71) Applicant: QUALCOMM Incorporated, San Diego, CA (US)

(72) Inventors: Rajagopalan Rangarajan, San Diego, CA (US); Chirag Dipak Patel, San Diego, CA (US)

(73) Assignee: QUALCOMM Incorporated, San Diego, CA (US)

(21) Appl. No.: 13/974,631

(22) Filed: Aug. 23, 2013

(51) Int. Cl. H04B 1/10; H03F 3/19

(52) U.S. Cl. CPC H04B 1/10; H03F 3/19; H03F 2200/294; H03F 2200/451
USPC 455/311; 330/302

(57) ABSTRACT

A circuit, a method and an apparatus, are described. A radio frequency (RF) signal received from a transmission line is provided to the source of a transistor in a common-gate amplification circuit. A series resonance connected to the source provides a low impedance path to ground for interfering RF components in the RF signal. The series resonance is tuned to provide a high impedance to a band of frequencies centered on a frequency of interest and to shunt interfering RF components outside the band of frequencies centered on the frequency of interest. The interfering RF components may include a harmonic of the frequency of interest.

### BACKGROUND

1. Field

Various features relate generally to wireless communications apparatus and more particularly to circuits and methods for removing interfering signals in a low noise amplifier of a wireless receiver.

2. Background

Wireless communications systems are widely deployed to provide various types of communication content such as voice, video, packet data, messaging, broadcast, and so on. These systems may be accessed by access terminals adapted to facilitate wireless communications, where multiple access terminals share the available system resources (e.g., time, frequency, and power). Examples of such wireless communications systems include code-division multiple access (CDMA) systems, time-division multiple access (TDMA) systems, frequency-division multiple access (FDMA) systems and orthogonal frequency-division multiple access (OFDMA) systems. A base station may provide the access terminal with access to a radio access network (RAN) using one or more radio access technology (RAT).

Responsive to increasing demand for greater functionality in apparatus including cellular telephones, smart phones, global positioning satellite (GPS) navigators, media players and the like, a growing number of wireless service operators are deploying RANs using a variety of RATs, at least some of which may interfere with one another. Many access terminals are configured for use with multiple RATs and/or may encounter different RATs while communicating on a preferred RAN. Coexistence issues can arise when the different RATs employ or share the same band of frequencies. For example, the wireless fidelity (WiFi) standard for local wireless communications defined by the Institute Of Electrical And Electronic Engineers (IEEE) as IEEE 802.11 may interfere with a wide area network (WAN) employing cellular network technologies. WiFi co-existence with WANs can present challenges to WAN sensitivity in radio frequency (RF) receivers.

Accordingly, there is an ongoing need for improved interference elimination circuits and devices.

### SUMMARY

In an aspect of the disclosure, a method and an apparatus are provided. The apparatus and method may be employed in a wireless networking environment. The apparatus may include a low-noise amplifier in high frequency RF receiver.

In an aspect of the disclosure, the apparatus includes a common-gate amplification circuit including a metal-oxide semiconductor field effect transistor (MOSFET), which may have a source terminal that is configured to receive an RF signal from a transmission line, and a series resonance comprising capacitance connected in series with an inductance. The series resonance may provide a low impedance path to ground for interfering RF components in the RF signal.

In an aspect of the disclosure, the series resonance is tuned to provide a high impedance to a band of frequencies centered on a frequency of interest. The interfering RF components may be characterized by frequencies outside the band of frequencies centered on the frequency of interest. The interfering RF components may include a harmonic of a frequency in the band of frequencies centered on the frequency of interest. The interfering RF components may include a harmonic generated in the transmission line. The band of frequencies may be centered on the frequency of interest corresponds to a band of frequencies associated with a first RAN. The interfering RF components may include a signal transmitted by a second RAN.

In an aspect of the disclosure, the signal transmitted by the second radio access network includes a carrier signal that is a harmonic of a frequency in the band of frequencies centered on the frequency of interest. The second RAN may include a WiFi network.

In an aspect of the disclosure, an output of the common-gate amplification circuit is down-converted using a local oscillator frequency corresponding to the frequency of interest. The interfering RF components may include a signal that has a frequency that is a harmonic of a local oscillator frequency.

In an aspect of the disclosure, a parallel resonance may be configured to reduce gain of frequencies outside the band of frequencies centered on the frequency of interest. The parallel resonance may include a second capacitance connected in parallel with a degeneration inductance that matches the transmission line.

In an aspect of the disclosure, a method of wireless communication includes providing an RF signal received from an antenna to an input of a common-gate amplification circuit, shunting the interfering RF component to ground through a resonating circuit coupled to the input of the common-gate amplification circuit, and passing the band of frequencies through the common-gate amplification circuit. The RF signal may include information encoded in a band of frequencies and an interfering RF component.

In an aspect of the disclosure, the resonating circuit may include a capacitance that is connected in series to an inductance. The capacitance and the inductance may have values selected to cause the resonating circuit to provide a low impedance path to ground for a frequency corresponding to the interfering RF component.

In an aspect of the disclosure, a parallel resonance may be provided at an output of a common source low noise amplifier that drives the transmission line. The parallel resonance may include a second capacitance connected in parallel with a degeneration inductance associated with the transmission line.

In an aspect of the disclosure, a wireless device includes means for amplifying an RF signal received from an antenna, and means for shunting an interfering RF component of the RF signal to ground. The means for shunting may include a resonating circuit coupled to an input of the common-gate amplification circuit. The RF signal may be received at an input of a common-gate amplification circuit. The RF signal may include information encoded in a band of frequencies and/or on a plurality of carriers and/or subcarriers. The means for amplifying may be configured to provide an amplified version of the RF signal to a local oscillator used to down-convert the band of frequencies.

### BRIEF DESCRIPTION OF THE DRAWINGS

FIG. 1 is a diagram illustrating networking environment in which a wireless apparatus can receive signals from multiple transmitters.

FIG. 2 is a block diagram illustrating an access terminal that is configured to receive signals from different types of networks.

FIG. 3 is a circuit diagram illustrating certain aspects of a wireless transceiver.

FIG. 4 is a circuit diagram illustrating a receive chain in a transceiver according to certain aspects described herein.

FIG. 5 is a schematic circuit diagram illustrating a common gate low noise amplifier conditioned using a series resonant circuit according to certain aspects described herein.

FIG. 6 is a circuit diagram illustrating illustrates the use of a series L-C circuit according to certain aspects described herein.

FIG. 7 is a flowchart of a method for wireless communication.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Several aspects of electrical circuits, assemblies, ICs, and IC packaging will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented in, or interact with electronic hardware, computer software, or any combination thereof.

The various concepts presented throughout this disclosure may be implemented across a broad variety of telecommunication systems, network architectures, and communication standards. Certain aspects of the discussions described below are described in relation to Global System for Mobile Communications (GSM), and in relation to 3rd Generation Partnership Project (3GPP) protocols and systems, and related terminology may be found in much of the following description. However, those of ordinary skill in the art will recognize that one or more aspects of the present disclosure may be employed and included in one or more other wireless communication protocols and systems.

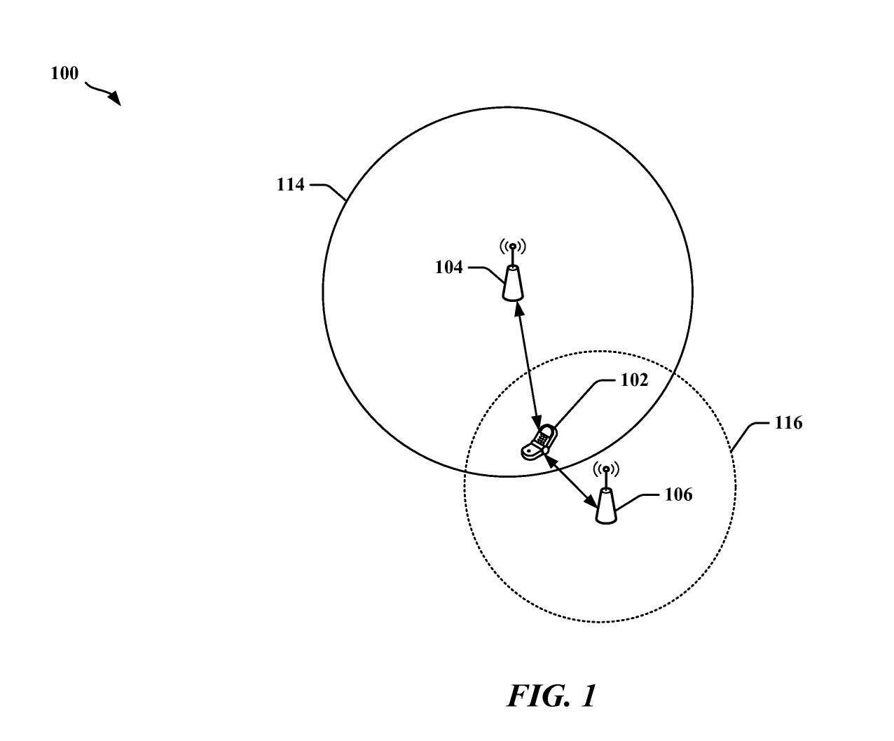

FIG. 1 is a diagram illustrating a mobile device 102 that is located within range of two or more different and distinct RANs 114, 116. The mobile device 102 may be a cellular phone, a smart phone, a session initiation protocol phone, a laptop computer, a personal digital assistant, a satellite radio, a global positioning system, a multimedia device, a video or audio streaming device, a video device, a digital audio player, a camera, a game console, a tablet, or any other similar functioning device. The two or more RANs 114 and 116 may be implemented using any combination of RATs. The two or more RANs 114 and 116 may comply or be compatible with the same or different telecommunication standards, and may employ any of a variety of modulation and multiple access techniques associated with the RANs 114 and 116.

The mobile device 102 may be configured to communicate with a first access point (AP) 104 to obtain services from a first network through RAN 114 and to communicate with a second AP 106 to obtain services from a second network associated with RAN 116. Each RAN 114 and 116 may provide voice and/or data services for subscribed users. RANs 114 and 116 may be operated by the same or different network operators. The geographical areas covered by RANs 114 and 116 may differ in size and/or may at least partially overlap. In one example, RAN 116 may be a WiFi network that covers a substantially smaller area than a GSM network 114. The access terminal 102 may be deployed in a location where multiple accessible cells or RANs 114 and 116 are available and the access terminal 102 may be configured to access a plurality of networks, and/or a single core network through multiple access points 104 and 106. Accordingly, the access terminal 102 may be capable of receiving wireless communications signals on different carrier frequencies and/or in different sub-bands associated with the carrier frequencies. It will be appreciated that information may be encoded on one or more subcarriers found in a band of frequencies.

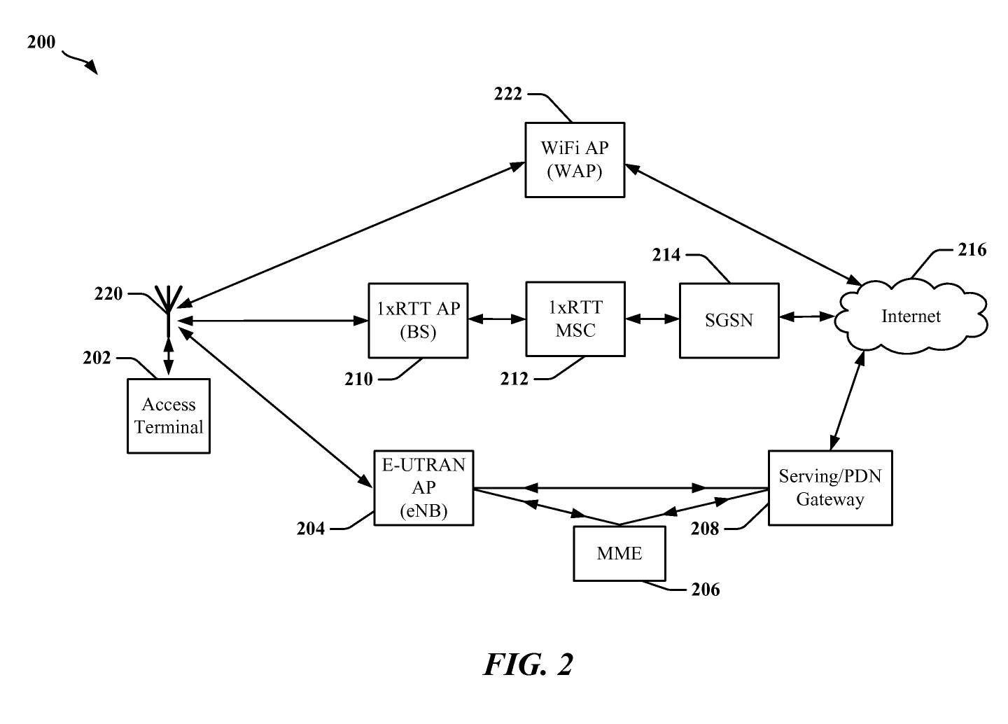

FIG. 2 is a simplified block diagram 200 illustrating a wireless networking environment. An access terminal 202 may include or be coupled to an antenna 220 that can receive signals from one or more APs 204, 210 and/or 222. The access terminal 202 may be a cellular phone, a smart phone, a session initiation protocol phone, a laptop computer, a personal digital assistant, a satellite radio, a global positioning system, a multimedia device, a video or audio streaming device, a video device, a digital audio player, a camera, a game console, a tablet, or any other similar functioning device. The access terminal 202 may be referred to as a mobile terminal, a wireless terminal, a remote terminal, a wireless terminal, user equipment, a user agent, a wireless device, a wireless communications device, a mobile device, a mobile wireless device, a mobile station, a subscriber station, a handset, a mobile client, a wireless client, or by some other suitable terminology.

Each of the APs 204, 210 and/or 222 may include, or be referred to as a base station, a base transceiver station, a radio access point, an access station, a radio transceiver, a basic service set, an extended service set, a Node B, an evolved Node B (eNB), a wireless hub, a WiFi Access Point (WAP) or by some other suitable terminology. Each AP 204, 210 and/or 222 may support a RAN that provides access to core network services provided by one or more network operators. RANs may be implemented using any suitable RAT and may be compatible or comply with telecommunication standards employing a variety of modulation and multiple access techniques. By way of example, RANs associated with the APs 204, 210 and/or 222 may include one or more of Universal Terrestrial Radio Access (UTRA) employing CDMA or one of its variants, such as Wideband-CDMA (W-CDMA); GSM employing TDMA, Time Division Synchronous Code Division Multiple Access (TD-SCDMA), Long Term Evolution (LTE) which is a set of enhancements to the Universal Mobile Telecommunications System (UMTS), Evolved UTRA (E-UTRA), Wi-Fi, IEEE 802.16 (WiMAX), IEEE 802.20, and Flash-OFDM employing OFDMA. RANs may also include one or more of Evolution-Data Optimized (EV-DO) or Ultra Mobile Broadband (UMB). An access terminal 202 may support multiple antennas to handle different network technologies. For example, an access terminal 202 may have different antennas for a 3GPP defined network, a WiFi network and/or a Bluetooth network.

The access terminal 202 may be connected to one or more of the APs 204, 210 and 222 and the antenna 220 may receive or detect signals from multiple APs 204, 210 and 222 at any given time. In one example, the access terminal 202 may be connected to the Internet through a WAP 222 while associated with a packet-switched (PS) network, such as LTE, through eNB 204 and/or with a circuit-switched (CS) network for data and voice calls through base station 210. The access terminal 202 may be registered with an E-UTRAN through the eNB 204 and a packet data network (PDN) gateway 210 may provide connectivity between the access terminal 202 and one or more external packet data networks such as the Internet 216. The access terminal 202 may be registered with a CS network through the base station 210 in order to obtain voice and data services through a CDMA-2000 network, for example. In one example, a general packet radio service (GPRS) system permits 2G, 3G and W-CDMA mobile networks to transmit IP packets to external networks such as the Internet 216 using a gateway function which may include a serving GPRS support node (SGSN) 214 to provide interworking services including access to an external packet switched networks such as the Internet 216.

Each of the APs 204, 210 and 222 may communicate with the access terminal 202, using predefined carrier frequencies and bands of frequencies. In some instances, frequency bands used by one of the APs 204, 210 and/or 222 may overlap frequency bands used by the other APs 204, 210 and/or 222. Although wireless networking protocols may include provisions that accommodate and avoid interference caused by overlapping frequency bands, interference may affect the operation of the antenna and the amplifiers and signal processors that extract signals from modulated carriers.

Referring again to FIG. 1, in some instances the mobile device 102 may simultaneously communicate with two or more access points 104 and 106 to obtain improved service using multiple antennas. In one example, the 3GPP standards define modes of operation of the downlink, including multiple-input, multiple-output (MIMO). MIMO is a term generally used to refer to multi-antenna technology, that is, multiple transmit antennas (multiple inputs to the channel) and multiple receive antennas (multiple outputs from the channel). MIMO systems generally enhance data transmission performance, enabling diversity gains to reduce multipath fading and increase transmission quality, and spatial multiplexing gains to increase data throughput.

Spatial multiplexing may be used to transmit different streams of data simultaneously on the same frequency. The data steams may be transmitted to a single mobile device 102 to increase the data rate or to multiple mobile devices 102 to increase the overall system capacity. This is achieved by spatially precoding each data stream and then transmitting each spatially precoded stream through a different transmit antenna on the downlink. The spatially precoded data streams arrive at the mobile device 102 with different spatial signatures, which enables the mobile device 102 to recover the one or more the data streams.

Receiver circuits in an access terminal 202 may be connected to one or more antennas 220, may receive a plurality of signals on carrier signals that have different or the same frequency, and may be subject to interference from signals received through the one or more antennas 220. According to certain aspects described herein, the access terminal 202 may be configured to eliminate, minimize or compensate for interference before down-conversion at a local oscillator. A local oscillator is a circuit that is used to convert an RF signal of interest to a lower frequency in a process referred to herein as down-converting the RF signal. In one example, a signal carried on a 5 GHz carrier may be down-converted to a signal that is encoded on a lower frequency carrier, known as an intermediate frequency, prior to decoding the RF signal.

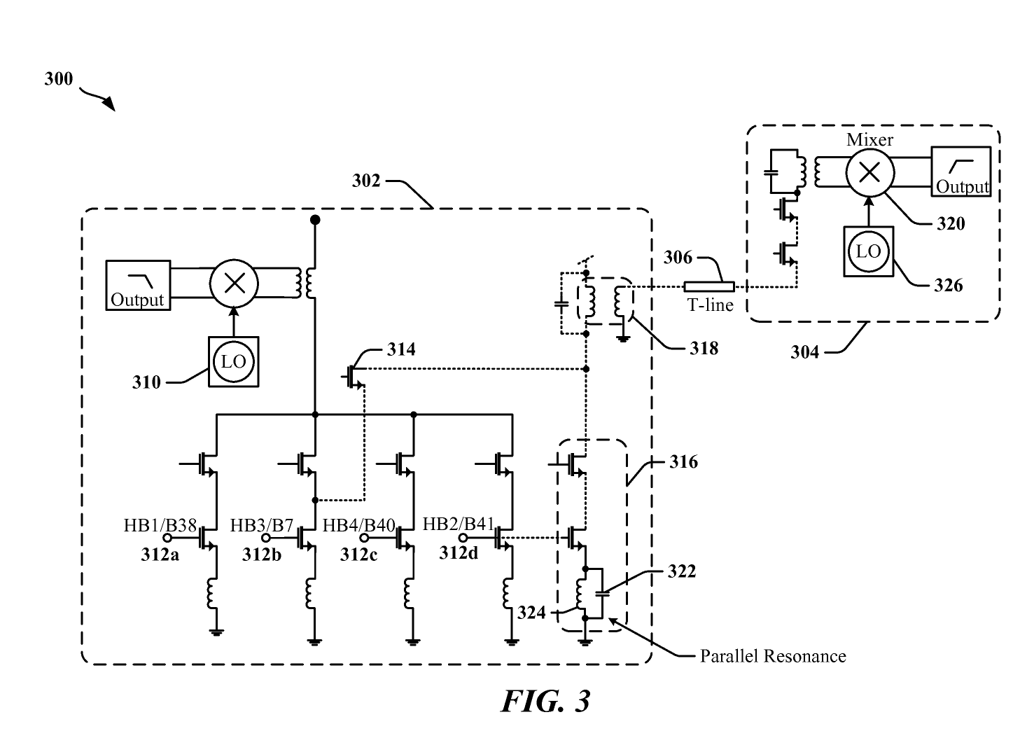

FIG. 3 is a circuit diagram 300 illustrating certain aspects of a wireless transceiver. The transceiver may include a low noise amplifier and down-converter that can be used to process signals received from the antenna 220 in FIG. 2. The transceiver may interact with an RF front-end and may accommodate a plurality of frequency bands and band combinations. In the illustrated example, the transceiver may be configured to handle four RF signals received at input ports 312a, 312b, 312c and 312d, which may be received from one or more antennas 220 (see FIG. 2) and which can be processed as individual signals and/or as MIMO signals. In one example, the local oscillator 310 may be used to combine MIMO signals received as RF signals 312a, 312b, 312c and/or 312d. In another example, different high-frequency bands (HBs) may be supported and one or more of the RF signals 312a, 312b, 312c and/or 312d may be amplified (e.g. through transistor 314 and/or low-noise amplifier 316) and transmitted between physically different devices 302 and 304 over a transmission line 306.

A multi-port device 302 may include a plurality of ports 312a, 312b, 312c and 312d that receive RF signals at one or more carrier frequencies. For example, two ports 312a and 312b may receive RF signals on 2.6 GHz carriers corresponding to band B38 (HB1) band B7 (HB3) respectively, one another port 312c may receive an RF signal on a 2.3 GHz carrier corresponding to band B40 (HB4), and another port 312d may receive an RF signal on a 2.5 GHz carrier corresponding to band B41 (HB2). In the illustrated example, a signal-of-interest designated as HB2 is received at a first port 312d, and provided through a low-noise amplifier 316 and an interface circuit 318 to the transmission line 306. The transmission line communicates the current-amplified HB2 signal to a device 304 having a low-noise amplifier (LNA) that is configured to down-convert the HB2 signal using a mixer 320 and associated local oscillator 326. The operation of down-converting mixer 320 may be affected by interfering signals and/or carriers associated with one or more of the other ports 312a, 312b and/or 312c. In the illustrated example, an interfering or jammer RF signal received at a second input port 312b may be coupled to the transmission line 306 through transformer 318.

When multiple RF signals 312a, 312b, 312c and/or 312d are received on different carrier frequencies by one or more antennas 220, co-existence issues may arise. Some co-existence issues may relate to the mixing down of jammer signals that have frequencies at harmonics of the local oscillator (LO) 326 used to obtain a baseband signal from the signal of interest 312d. In one example, the jammer signal may be a WiFi signal detected by an antenna 220 on a carrier frequency of 5 GHz. As illustrated in FIG. 3, the 5 GHz jammer signal may be present at the HB3 signal input 312b. The jammer signal may be derived from a WiFi carrier, and may be conducted through a bridge (e.g. through the path indicated with dotted lines). The 5 GHz WiFi signal may be approximately twice the frequency of the local oscillator 326 provided to down-convert the B41 signal received at the first input port 312d. The jamming signal may desensitize the down-converter 304 by down-converting the B41 signal 312d.

One approach to reducing the impact of the jammer signal is to provide a parallel resonance at the source of the common-source amplifier 316 to reduce the gain at an out-of-band frequency. The parallel resonance may be formed by adding a capacitance 322 in parallel with a degeneration inductor 324, which is used to match the impedance of an input of the amplifier 302. The parallel resonance formed from the inductance 324 and capacitance 322 may operate as a filter that reduces the gain at the out-of-band frequency and may therefore ameliorate the problems attributable to the jammer signal. An inductance-capacitance (LC) value may be selected to obtain low pass filtering in order to attenuate the higher frequencies. However, noise figure degradation of 0.1 dB-0.2 dB or higher may result.

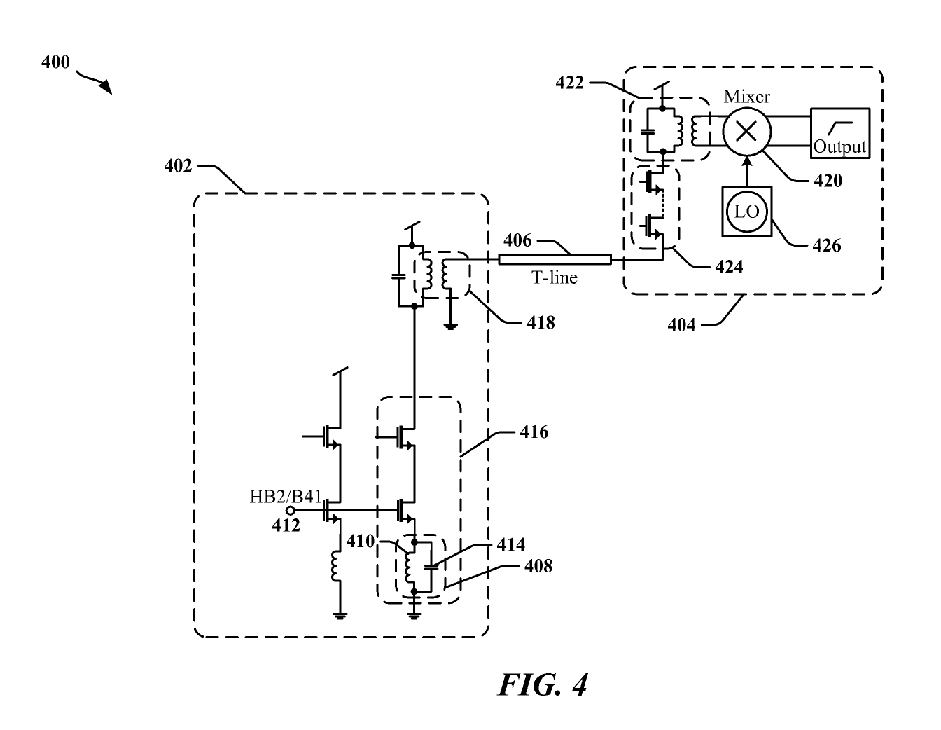

FIG. 4 is a circuit diagram 400 illustrating a receive chain in a transceiver. The receive chain may be configured to handle a band B41 RF signal received at an input port 412. The B41 RF signal may be received on a 2.5 GHz carrier, for example. The RF signal received at the input port 412 is provided to the low-noise amplifier 416. A coupling transformer circuit 418 may transmit the signal through transmission line 406 to a low noise amplifier 424, which causes the signal to be mixed at mixing circuit 420 with a signal produced by the local oscillator 426. The load of the LNA 424 may be a parallel resonant circuit 422 that provides a high impedance at the carrier frequency of the signal of interest and provides a low impedance path to the jammer signal. A degeneration impedance 408, which includes a degeneration inductance 410, and capacitance 414 form a parallel resonance circuit that operates as a band-stop filter at the interfering frequency, which can attenuate certain interfering signals before the transmission line 406. The degeneration impedance 408 may not provide enough filtering at the interfering frequencies due to design constraints. Further, due to mismatched termination impedance on T-line 406, standing waves may be produced at the harmonic frequencies that increase harmonic interference and affect the decoding of the signal of interest, which further reduces the effectiveness of circuit 408 in interference rejection. Even further, there may be interferers at multiple frequencies, and the circuit 408 may be able to reject only one of the frequencies. In this case, another filter may be used to reject the other interfering frequency or frequencies. According to certain aspects disclosed herein, certain circuits may be provided after the transmission line 406 in order to eliminate or reduce the impact of harmonic interference.

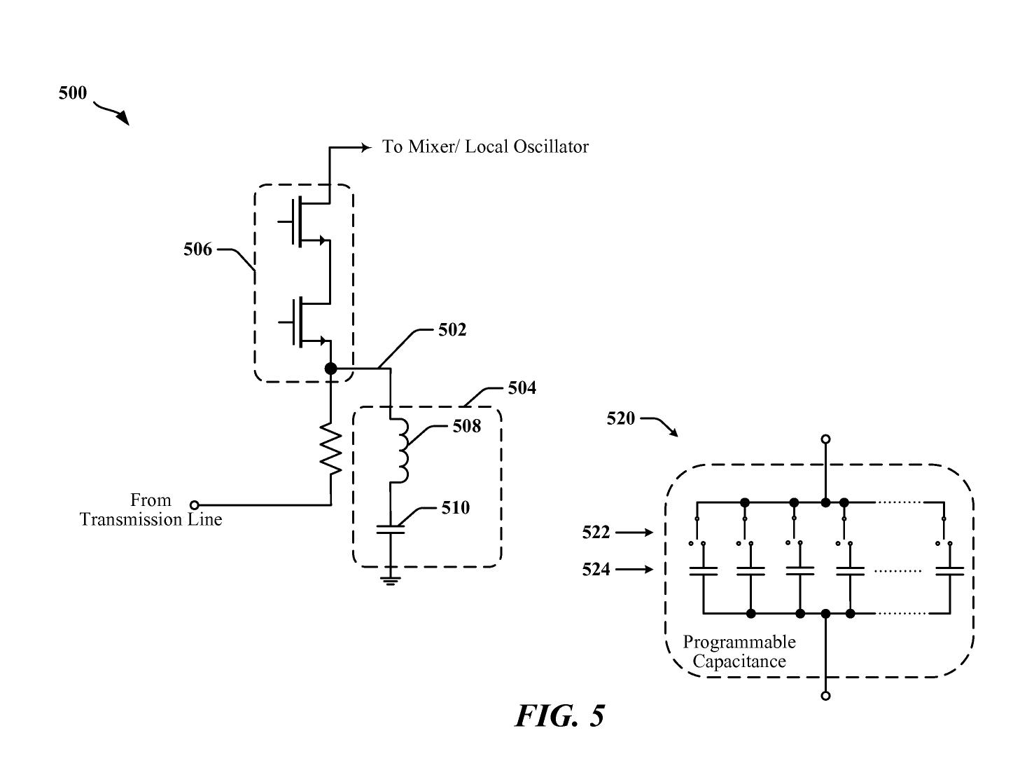

FIG. 5 is a schematic circuit diagram 500 illustrating a common gate LNA 506 that is conditioned using a series resonant circuit 504. The series resonant circuit 504 may be connected to an input of the LNA 506 in order to combat interference from out-of-band jammer or blocker signals. In one example, the series resonant circuit 504 has an inductance 508 and a capacitance 510 that have values selected to shunt an out-of-band jammer signal which may be observed or expected at a frequency which is a harmonic of the frequency of the local oscillator 426 (see FIG. 4). In one example, the out-of-band jammer signal occurs at the second harmonic of the local oscillator 426. The series resonant circuit 504 may operate as a notch filter that shunts signals at the resonant frequency to ground. The series resonant circuit 504 may be configured to effectively short a targeted jammer signal, thereby reducing gain of the out-of-band jammer signal before it reaches the down-converter mixer 420 and local oscillator 426. The series resonant circuit 504 may operate as a harmonic trap that can achieve out-of-band jammer rejection of better than 7 dB.

In some examples, the series resonant circuit 504 may be tunable and can be digitally controlled to resonate at one of a plurality of frequencies corresponding to various potential jamming signals. The series resonant circuit 504 may be tuned by varying the inductance 508 or capacitance 510. An example of a digitally programmable capacitance element 520 is depicted in FIG. 5. The programmable capacitance element 520 may include switches 522 that are digitally controlled to connect corresponding capacitances 524 in parallel in order to adjust the capacitance provided by the capacitance element 520. The position of each switch 522 may be determined by configuration information that may vary according a current mode of operation.

In some examples, a plurality of series resonant circuits 504 may be provided, each series resonant circuit 504 being tuned to target a specific interferer. In some instances, there may be multiple interferers that desensitize the receiver. For example, interferers may be present at 5.4 GHz and 7 GHz in the system.

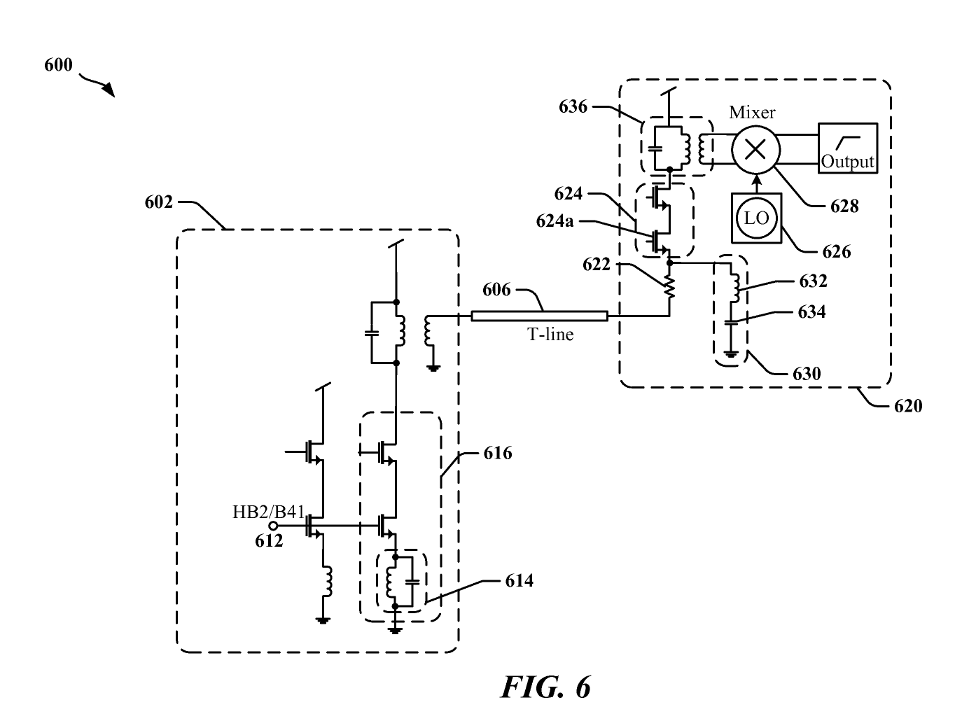

FIG. 6 is a schematic circuit diagram 600 illustrating a receive chain that employs multiple resonant filters 614, 636 and 630. An RF signal of interest in a band B41 that is carried on a 2.5 GHz carrier is received at an input port 612 and provided to the low-noise amplifier 616. A parallel resonance circuit 614 may be provided at the source of the amplifier 616. The parallel resonance circuit 614 operates as a low-pass filter that can block potentially interfering higher frequency signals from traversing the transmission line 606. The output of the amplifier 616 is transmitted over the transmission line 606 to the LNA 624. An impedance, such as resistance 622, may be provided to match the characteristic impedance of the transmission line 606.

The low noise amplifier 624 may be configured to drive a mixing circuit 628 that down-converts the signal of interest using a local oscillator 626. The LNA 624 may be a common-gate amplifier. A signal received from the transmission line 606 is provided to a source terminal of a transistor 624a in the LNA 624. In accordance with certain aspects disclosed herein, a series resonance 630 may be connected to the source terminal of the transistor 624a. The series resonance 630 may have an inductance 632 that is series connected with a capacitance 634 such that the series resonance 630 is tuned to provide a low impedance path to ground for certain targeted frequencies. The series resonance 630 may be tuned through the selection of the values of inductance 632 and capacitance 634. In one example, the series resonance 630 may be tuned to shunt signals having a frequency around a harmonic of the frequency of the local oscillator 626 and/or to filter harmonics generated in the transmission line 606.

The series resonant circuit 630 may be combined with the parallel resonance 614 to improve the out-of-band jammer signal rejection characteristics of the receive chain. The series resonant circuit 630 may be provided after or near the termination impedance 622 of the transmission line 606 and/or at or near the input to the LNA 624, while other filters are deployed to improve the rejection of signals at one or more harmonic frequencies of the local oscillator 626 and/or signals at frequencies that are not harmonics of the local oscillator frequency. For example, the load of the LNA 624 may be a parallel resonant circuit 636 that provides a high impedance at the carrier frequency of the signal of interest and provides a low impedance path to the jammer signal. In another example, a combination of the parallel resonant circuit 614 and the series resonant circuit 630 may be employed, and may yield a 16 dB or better rejection of interfering harmonics for the entire receive chain, and without incurring a significant noise figure penalty.

In some examples, a plurality of series resonant circuits 630 may be provided, each series resonant circuit 630 being tuned to target a specific interferer. Alternatively or additionally, the combination of the series resonant circuit 630 with the parallel resonance 614 may be configured to improve the out-of-band jammer signal rejection characteristics of the receive chain when multiple interferers are present. According to one aspect, one resonant circuit 614 or 630 may be tuned to reject one interferer when there are multiple interferers that can desensitize the receiver, and the other resonant circuit 630 or 614 may be tuned to reject interferers at other frequencies. For example, there may be interferers at 5.4 GHz and 7 GHz in the system, and the parallel resonant circuit 614 may be tunable to reject only the 5.4 GHz interferers, in which case the series resonant circuit 630 may be tuned to reject the 7 GHz interferer.

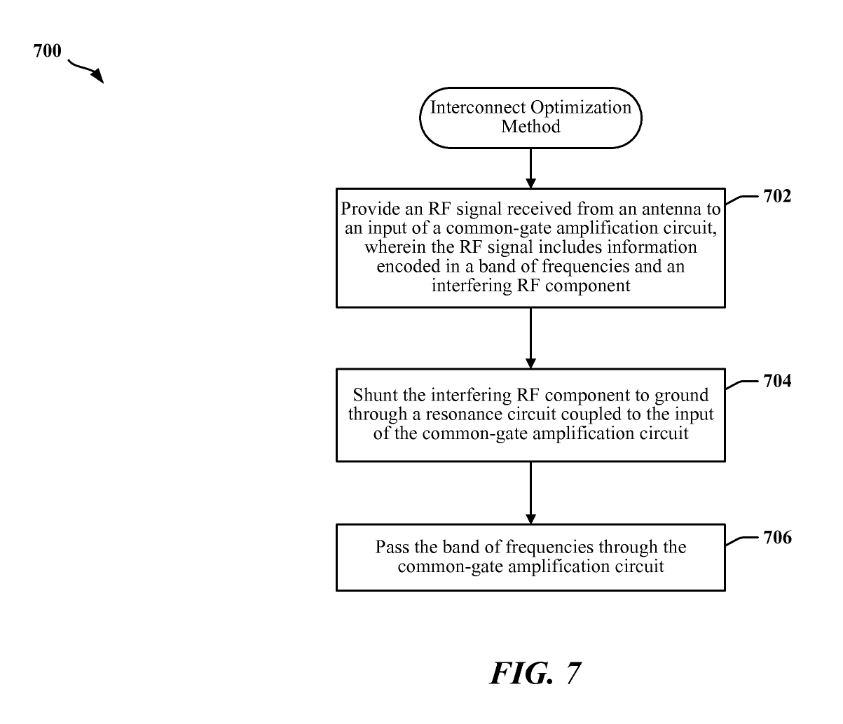

FIG. 7 is a flowchart 700 illustrating a method for wireless communication. At step 702, an RF signal received from an antenna is provided to an input of a common-gate amplification circuit. The RF signal may be provided to a source terminal of a transistor in the common-gate amplification circuit. The RF signal may include information encoded in a band of frequencies and an interfering RF component. The band of frequencies may be associated with a first carrier frequency, and the interfering RF component may be associated with a second carrier frequency. The band of frequencies may be transmitted on the first carrier frequency by a first RAN and the interfering RF component may be associated with a signal transmitted in a second RAN. The second RAN may be a WiFi network. The interfering RF component may be an out-of-band blocker signal received from a WiFi network. The WiFi network may transmit on an RF carrier at a frequency of 5 gigahertz. The out-of-band blocker signal may be a second harmonic of the RF carrier associated with a signal of interest.

At step 704, the interfering RF component is shunted to ground through a series resonance circuit coupled to the input of the common-gate amplification circuit. The resonance circuit may include a capacitance that is connected in series to an inductance. The capacitance and the inductance may have values that are selected to cause the resonance circuit to provide a low impedance path to ground for a frequency corresponding to the interfering RF component. The interfering RF component may have a frequency that is a harmonic of a local oscillator used to down-convert the band of frequencies. Further, the capacitor and/or inductor may be tunable by using a switched network for capacitors and switched ports for inductors. The interfering RF component may include a signal that has a frequency that is a harmonic of a local oscillator used to down-convert the band of frequencies. The interfering RF component may include a signal that is increased in the transmission line.

In an aspect of the disclosure, the series resonance circuit is tunable. In one example, the series resonance circuit may be tuned to target one of a plurality of potentially interfering RF components in the RF signal. In another example, the series resonance circuit is one of a plurality of series resonance circuits connected to the source of the MOSFET, each series resonance circuit being tuned to provide a low impedance path to ground for a different interfering RF component in the RF signal. In an aspect of the disclosure, a parallel resonance circuit is used to target an interfering RF component in the RF signal that is different from interfering RF components targeted by one or more series resonance circuits.

At step 706, the band of frequencies is passed through the common-gate amplification circuit. According to certain aspects described herein, the RF signal may be filtered before it is transmitted over a transmission line. The RF signal may be filtered before the transmission line by providing the RF signal to a parallel resonance that may be provided at a source terminal of a common source low noise amplifier that drives the transmission line, for example. The parallel resonance may have a second capacitance connected in parallel with a degeneration inductance that may be used to match the impedance of an input of the amplifier.

According to certain aspects described herein, the RF signal received from the antenna is amplified using a current amplifier, and an output of the current amplifier is provided to a first end of a transmission line. The RF signal may be filtered using a parallel resonance coupled to a source terminal of a transistor in the current amplifier. The input of the common-gate amplification circuit may be coupled to a second end of the transmission line. The parallel resonance may comprise a second capacitance connected in parallel with a degeneration inductance that is configured to provide impedance matching of an input port that receives the RF signal from the antenna.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “source/drain” terminal of a transistor may be either the source or the drain of the transistor. Whether it is actually the source or the drain depends on the voltages applied to the various terminals of the transistor when it is in operation. Moreover, the term “V_{DD}” represents the circuit's power supply voltage, and “V_{SS}” represents the circuit ground.

The terms wafer and substrate may be used herein to include any structure having an exposed surface with which to form an IC according to aspects of the present disclosure. The term “die” may be used herein to include an IC. A die may include one or more circuits. The term substrate is understood to include semiconductor wafers. The term substrate is also used to refer to semiconductor structures during fabrication, and may include other layers that have been fabricated thereupon. The term substrate includes doped and undoped semiconductors, epitaxial semiconductor layers supported by a base semiconductor, or semiconductor layers supported by an insulator, as well as other semiconductor structures well known to one skilled in the art.

One or more of the components, steps, features and/or functions illustrated in FIGS. 1-7 may be rearranged and/or combined into a single component, step, feature or function or embodied in several components, steps, or functions. Additional elements, components, steps, and/or functions may also be added without departing from novel features disclosed herein. The apparatus, devices, and/or components illustrated in FIGS. 1-6 may be configured to perform one or more of the methods, features, or steps described herein, including the methods illustrated by FIG. 7. The novel algorithms described herein may also be efficiently implemented in software and/or embedded in hardware.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A low-noise amplifier comprising:
a common-gate amplification circuit including a metal-oxide semiconductor field effect transistor (MOSFET) having a source that is configured to receive a radio frequency (RF) signal from a transmission line; and
a series resonance connected to the source of the MOSFET and comprising a capacitance connected in series with an inductance, wherein the series resonance provides a low impedance path to ground for interfering RF components in the RF signal.

2. The low-noise amplifier of claim 1, wherein the series resonance is tuned to provide a high impedance to a band of frequencies centered on a frequency of interest.

3. The low-noise amplifier of claim 2, wherein the interfering RF components are characterized by frequencies outside the band of frequencies centered on the frequency of interest.

4. The low-noise amplifier of claim 2, wherein the interfering RF components comprise a harmonic of a frequency in the band of frequencies centered on the frequency of interest.

5. The low-noise amplifier of claim 2, wherein the series resonance is tunable to target one of a plurality of potentially interfering RF components in the RF signal.

6. The low-noise amplifier of claim 2, wherein the band of frequencies centered on the frequency of interest corresponds to a band of frequencies associated with a first radio access network and wherein the interfering RF components include a signal transmitted by a second radio access network.

7. The low-noise amplifier of claim 6, wherein the signal transmitted by the second radio access network includes a carrier signal that is a harmonic of a frequency in the band of frequencies centered on the frequency of interest.

8. The low-noise amplifier of claim 7, wherein the second radio access network comprises a wireless fidelity (WiFi) network.

9. The low-noise amplifier of claim 2, wherein an output of the common-gate amplification circuit is down-converted using a local oscillator frequency corresponding to the frequency of interest, and wherein the interfering RF components includes a signal that has a frequency which is a harmonic of the local oscillator frequency.

10. The low-noise amplifier of claim 2, wherein a parallel resonance configured to reduce gain of frequencies outside the band of frequencies centered on the frequency of interest.

11. The low-noise amplifier of claim 10, wherein the parallel resonance targets an interfering RF component in the RF signal that is different from interfering RF components targeted by the series resonance.

12. The low-noise amplifier of claim 1, wherein the series resonance is one of a plurality of series resonances connected to the source of the MOSFET, each series resonance being tuned to provide a low impedance path to ground for a different interfering RF component in the RF signal.

13. A method of wireless communication comprising:
providing a radio frequency (RF) signal received from an antenna to an input of a common-gate amplification circuit, wherein the RF signal includes information encoded in a band of frequencies and an interfering RF component;
shunting the interfering RF component to ground through a resonating circuit coupled to the input of the common-gate amplification circuit; and
passing the band of frequencies through the common-gate amplification circuit.

14. The method of claim 13, wherein the resonating circuit includes a capacitance that is connected in series to an inductance.

15. The method of claim 14, wherein the capacitance and the inductance have values selected to cause the resonating circuit to provide a low impedance path to ground for a frequency corresponding to the interfering RF component.

16. The method of claim 14, wherein the interfering RF components includes a signal that has a frequency which is a harmonic of a local oscillator used to down-convert the band of frequencies.

17. The method of claim 14, wherein the resonating circuit is tunable to target one of a plurality of potentially interfering RF components in the RF signal.

18. The method of claim 13, wherein providing the RF signal received from the antenna to the input of the common-gate amplification circuit includes:
amplifying the RF signal with a current amplifier, wherein an output of the current amplifier is provided to a first end of a transmission line; and
filtering the RF signal using a parallel resonance coupled to a source terminal of a transistor in the current amplifier.

19. The method of claim 18, wherein the input of the common-gate amplification circuit is coupled to a second end of the transmission line.

20. The method of claim 19, wherein the parallel resonance comprises a second capacitance connected in parallel with a degeneration inductance that is configured to provide impedance matching of an input port that receives the RF signal from the antenna.

21. The method of claim 18, wherein the parallel resonance targets an interfering RF component in the RF signal that is different from interfering RF components targeted by the resonating circuit coupled to the input of the common-gate amplification circuit.

22. The method of claim 13, wherein the band of frequencies is transmitted on a first carrier by a first radio access network and the interfering RF component is associated with a signal transmitted in a second radio access network.

23. The method of claim 22, wherein the second radio access network comprises a wireless fidelity (WiFi) network.

24. The method of claim 23, wherein the interfering RF component comprises an out-of-band blocker signal received from a WiFi network.

25. The method of claim 24, wherein the out-of-band blocker signal is transmitted at a second harmonic of an RF carrier.

26. The method of claim 13, wherein a plurality of resonating circuits is coupled to the input of the common-gate amplification circuit, each of the plurality of resonating circuits being tuned to provide a low impedance path to ground for a different interfering RF component in the RF signal.

27. A radio frequency (RF) receiver comprising:
means for amplifying an RF signal received from an antenna, wherein the RF signal is received at an input of a common-gate amplification circuit, and wherein the RF signal includes information encoded in a band of frequencies; and
means for shunting an interfering RF component of the RF signal to ground, wherein the means for shunting includes a resonating circuit coupled to an input of the common-gate amplification circuit,
wherein the means for amplifying is configured to provide an amplified version of the RF signal to a mixing circuit used to down-convert the band of frequencies.

28. The receiver of claim 27, wherein the resonating circuit is coupled to a source of a transistor in the common-gate amplification circuit and comprises a capacitance that is connected in series to an inductance.

29. The receiver of claim 28, wherein the capacitance and the inductance have values selected to cause the resonating circuit to provide a low impedance path to ground for frequencies corresponding to the interfering RF component.

30. The receiver of claim 28, wherein the interfering RF component includes a signal that has a frequency at a harmonic of a local oscillator of the mixing circuit.

31. The receiver of claim 27, further comprising means for filtering the RF signal before a transmission line used to carry the RF signal to the input of the common-gate amplification circuit.

32. The receiver of claim 31, wherein the means for filtering the RF signal before the transmission line includes a parallel resonance.

33. The receiver of claim 32, wherein the parallel resonance is provided at a source terminal of a common source low noise amplifier that drives the transmission line.

34. The receiver of claim 32, wherein the parallel resonance comprises a second capacitance connected in parallel with a degeneration inductance that is configured to provide impedance matching of an input port.

35. The receiver of claim 32, wherein the parallel resonance targets an interfering RF component in the RF signal that is different from interfering RF components targeted by the means for shunting.

36. The receiver of claim 27, wherein the band of frequencies is transmitted on a first carrier by a first radio access network and the interfering RF component is associated with a signal transmitted in a second radio access network.

37. The receiver of claim 36, wherein the second radio access network comprises a wireless fidelity (WiFi) network.

38. The receiver of claim 36, wherein the interfering RF component comprises an out-of-band blocker signal received from a WiFi network.

39. The receiver of claim 38, wherein the out-of-band blocker signal is transmitted at a second harmonic of an RF carrier.
